(19) United States
(12) Patent Application Publication
(10) Pub. No.: US 2010/0098882 A1
(43) Pub. Date: Apr. 22, 2010

(54) PLASMA SOURCE FOR CHAMBER CLEANING AND PROCESS

(75) Inventors: Dmitry Lubomirsky, Cupertino, CA (US); Jang Gyoo Yang, San Jose, CA (US); Qiwei Liang, Fremont, CA (US); Matthew L. Miller, Fremont, CA (US); James Santosa, San Francisco, CA (US); Xinglong Chen, San Jose, CA (US); Paul F. Smith, Campbell, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/581,600

(22) Filed: Oct. 19, 2009

Related U.S. Application Data
(60) Provisional application No. 61/107,154, filed on Oct. 21, 2008.

(51) Int. Cl. C23C 16/50; C23C 16/00

(52) U.S. Cl. 427/569; 118/723 R

(57) ABSTRACT

Apparatus and methods for processing a substrate and processing a process chamber are provided. In one embodiment, an apparatus is provided for processing a substrate including a power source, a switch box coupled to the power source and the switch box having a switch interchangeable between a first position and a second position, a first match box coupled to the switch box, a plasma generator coupled to the first match box, a second match box coupled to the switch box, and a remote plasma source coupled to the second match box.

### CROSS-REFERENCE TO RELATED APPLICATIONS

This application claims benefit of U.S. Provisional Patent Application Ser. No. 61/107,154, filed Oct. 21, 2008, which is incorporated herein by reference in the entirety.

### BACKGROUND OF THE INVENTION

1. Field of the Invention

Embodiments of the invention generally relate to the field of semiconductor manufacturing processes and devices, more particular, to an apparatus for processing semiconductor substrates. More specifically, the invention relates to an apparatus for processing gases and substrates in a semiconductor substrate process chamber.

2. Description of the Related Art

Semiconductor substrate processing chambers are susceptible to particle generation caused by condensate from processing gasses or reactants formed during processing. When the condensate accumulates on the various components of the chamber, a residue forms and is susceptible to flaking. Such flaking generates the particles (or contaminants) that are undesirable, since they can drift onto a substrate during processing. These contaminants can subsequently create shorts or voids in the devices formed in the processed substrate thereby degrading the quality of the substrate.

In particular, during a plasma assisted chemical vapor deposition process, processing gases are introduced into a chamber containing a semiconductor substrate, i.e., substrate. The substrate is supported and retained on a substrate support circumscribed by a process kit. The process kit assists in controlling the distribution of the gas over the semiconductor substrate. Once a plasma is formed, the process gas reacts with the substrate and deposits a desired material layer. During this process, the inner walls of the chamber, the substrate support, and the process kit, are subjected to the aforementioned residue, particles, or contaminants.

Removal of the residue is typically accomplished via a cleaning agent that is injected into the chamber from a cleaning device that is attached to a wall of the chamber. The cleaning device comprises a container having the cleaning agent (e.g., fluorine). The cleaning agent is used to etch the undesirable residue from the inner chamber walls and substrate support devices.

The cleaning agent may be provided to a processing chamber as a plasma from a remote plasma source. The addition of an additional power source provides additional processing and apparatus complexity as well as limits effective power control of all of the processes and power source coupled to a processing chamber performing multiple processes such as deposition and cleaning.

Therefore, there is a need in the art for an apparatus and process that more effectively controls power applications and more efficiently uses power application and apparatus.

### SUMMARY OF THE INVENTION

Apparatus and methods for depositing a material on substrate and cleaning a process chamber are provided. In one embodiment an apparatus is provided for processing a substrate including a power source, a switch box coupled to the power source and the switch box having a switch interchangeable between a first position and a second position, a first match box coupled to the switch box, a plasma generator coupled to the first match box, a second match box coupled to the switch box, and a remote plasma source coupled to the second match box.

In another embodiment an apparatus is provided for processing a substrate including a chamber body having a dome portion, a plasma generator disposed on the chamber body, a remote plasma source disposed on the chamber body, a switch box coupled to the plasma generator and the remote plasma source with the switch box having a switch interchangeable between a first position and a second position, and a first power source coupled to the switch box.

In another embodiment, a method is provided for processing a substrate and processing a chamber including positioning a substrate into a processing chamber and the processing chamber including a chamber body, a plasma source disposed on the chamber body, a remote plasma source disposed on the chamber body, a switch box having first and second switch positions coupled to the plasma source and the remote plasma source, and a first power source coupled to the switch box, applying power from the first power source to a portion of the plasma generator through a switch in the first switch position, supplying a first processing gas into the chamber, generating a first plasma of the first processing gas in the chamber, applying power from the first power source to a remote power source through a switch in the second switch position, supplying a second processing gas into the remote plasma source, generating a second plasma of the second processing gas in the remote plasma source, and supplying the second processing gas to the chamber body.

In another embodiment, an apparatus is provided for processing a substrate including a power generator, a switch box having a switch interchangeable between a first position and a second position, a first integrated match box coupled to the switch box, a high density plasma source coupled to the first integrated match box, a second integrated match box coupled to the switch box, and a remote plasma source coupled to the second integrated match box.

In another embodiment, a method is provided for processing a substrate and processing a chamber including positioning a substrate into a processing chamber, applying power from the power generator to a high density power source through a switch in the first position, supplying a first processing gas into the chamber, generating a plasma of the first processing gas in the chamber, performing a plasma enhanced chemical vapor deposition process in the chamber, applying power from the power generator to a remote power source through a switch in the second position, supplying a second processing gas into the remote plasma source, generating a plasma of the second processing gas in the remote plasma source, and supplying the plasma to the chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic side view of one embodiment of a processing chamber suitable for practice the present invention;

FIG. 2 is a simplified sectioned perspective view of a portion of a plasma generator according to an embodiment of the present invention;

FIG. 3 is a simplified chart of one embodiment of a switch box according to an embodiment of the present invention;

FIG. 4 is a simplified sectioned perspective view of a portion of a plasma generator according to another embodiment of the present invention;

FIG. 5 is a simplified chart of one embodiment of coupled plasma sources according to an embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the invention provide methods for an apparatus that can deposit material on a substrate in a processing chamber and clean a processing chamber before or after a deposition process. The apparatus includes a power source for a plasma deposition, such as a high density plasma deposition through coils, in the processing chamber and a remote plasma source for providing a plasma of cleaning gases to the chamber. The power source for at least part of both components may be controlled by a switch box. The use of the power sources and switch box will allow for improved control over deposition and cleaning power applications, and power precision, and reduce apparatus complexity.

In one embodiment, an apparatus is provided for processing a substrate including a power source, a switch box having a switch interchangeable between a first position and a second position. A plasma generator and a remote plasma source are coupled to the power source. A first integrated match box is coupled to the switch box and the plasma generator, such as a high density plasma source, is coupled to the first integrated match box. A second integrated match box is coupled to the switch box and the remote plasma source coupled to the second integrated match box.

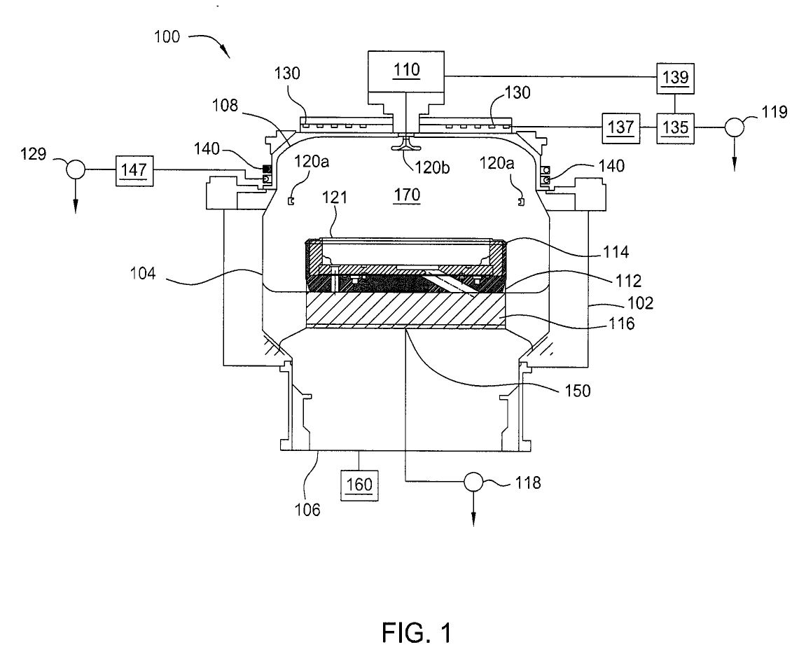

FIG. 1 depicts a schematic side view of one embodiment of a processing chamber suitable for practice the present invention. The processing chamber 100 may be utilized to practice a plasma deposition and plasma cleaning process according to one embodiment of the invention. Suitable process chambers with which the apparatus and method may be practiced includes an ULTIMA® High Density Plasma Chemical Vapor Deposition (HDP-CVD) system, and the Producer® series of chemical vapor deposition processing chambers and systems, such as the PRODUCER SE™ processing chamber and the PRODUCER GT™ processing chamber, all of which are commercially available from Applied Materials, Inc., of Santa Clara, Calif. It is contemplated that the methods described herein may be practiced in other suitably adapted plasma reactors, including those from other manufacturers. The processing chamber 100 may be one a number of substrate processing systems that are coupled to a semiconductor substrate processing platform such as a CENTURA® processing platform, available from Applied Materials, Inc.

While the following apparatus directed to power sources and a switch box is described with regard to a high density plasma source for chemical vapor deposition, the apparatus may be used in apparatus performing CVD dielectric deposition processes, metal deposition process, and atomic layer deposition processes.

The processing chamber 100 generally comprises a chamber body 102 and a remote plasma source 110 (RPS or RPS plasma source) disposed on the chamber body 102. Specifically, the chamber body 102 comprises side walls 104, a bottom 106, and a dome 108 that defines an evacuable chamber for carrying out substrate processing. The dome 108 is fabricated from a dielectric material such as ceramic, quartz, and the like. The processing chamber 100 includes a semiconductor substrate support 112 having a chuck 114, an electrode 116 coupled to a first power source, or generator, 118. A substrate 121 is retained to a top surface of the chuck 114 via chucking techniques known in the art, such as electrostatic chucking, vacuum chucking, and the like.

Processing gases are introduced into the chamber body 102 via one or more external processing gas source ports 120a, 120b from an external processing gas source (not shown). Deposition gases may be introduced through ports 120a that may be disposed around a circumference of the processing chamber 100 and may be disposed vertically from the substrate support 112 on the chamber side walls 104. Cleaning gases may be introduced into the processing chamber 100 via a dome port 120b from an external processing gas source (not shown). Alternatively, deposition gases and cleaning gases may be respectively introduced into the processing chamber via one or more of ports 120a and 120b.

A second power source, or generator, 119 external to the chamber body 102 provides RF power to a first plurality of coils 130 (high density plasma generator or source) disposed over the dome 108 (disposed on a top portion of the dome) of the processing chamber body 102 of the processing chamber 100, and, alternatively, to a second plurality of coils 140 (high density plasma generator or source) circumscribing the dome 108 (disposed along the sides of the dome) of the processing chamber body 102 of the processing chamber 100. Power applied to both coils 130 and coils 140 create an electric field proximate the injected gases and may be used to generate a high density plasma.

The second power source 119 is electrically coupled to the coils 130 through a switch box 135. A match box 137, such as an integrated fixed match box, may be disposed between the coils 130 and the switch box 135. A third power source 129 may be coupled to the coils 140. A match box 147, such as an integrated fixed match box, may be disposed between the third power source 129 and the coils 140. While not shown, a second switch box may be coupled to the third power source before the match box 147. The second switch box may of the same design as described for switch box 135 described herein. Alternatively, the second power source 119 is electrically coupled to the coils 140 through the switch box 135.

The coils 130 and 140 may be provided with the same power and frequencies. The coils 130 and 140 may also be independently provided power and frequencies. Power may also be provided with the same or different power levels to the respective coils 130, 140. For example, the second power source 119 may provide power to coils 130 at 10 kW with a frequency of 1.9 MHz, and the third power source 129 may provide power to coils 140 at 10 kW with a frequency of 2.1 MHz. In another example, the second power source 119 may provide power to coils 130 at 10 kW with a frequency of 1.9 or 2.1 MHz, and the third power source 129 may provide power to coils 140 at 10 kW with a frequency of 1.9 or 2.1 MHz

The second power source (RF source plasma supply) 119 is coupled to the coils 130, which coils 130 create a circulating plasma current in a first closed torroidal path including the process region 170. The third power source 129 of RF source power (or alternatively, the second power source 119) may be coupled to the coils 140, which creates a circulating plasma current in a second closed torroidal path transverse (e.g., orthogonal) to the first torroidal path. The plasma currents in each of the paths oscillate (e.g., reverse direction) at the frequencies of the respective RF source power generator. The electric field generated by the coils 130 and 140 excites the gases into a plasma state, such as a high density plasma. The excited process gases react with the semiconductor substrate 121 to form desired coatings and films (i.e., silicon oxide). Upon completion of the CVD process, the excess process and by-product gases are evacuated from the processing chamber 100 via exhaust port 160 connected to an external evacuation pump (not shown).

In an alternative embodiment of the power sources of the processing chamber 100, the second power source 119 is electrically coupled to the coils 130, 140 through a single switch box 135 and integrated match box 137. The second power source (RF source plasma supply) 119 is coupled to the coils 130, which coils 130 create a circulating plasma current in a first closed torroidal path including the process region 170 and the second power source 119 of RF source power may be coupled to the coils 140, which creates a circulating plasma current in a second closed torroidal path transverse (e.g., orthogonal) to the first torroidal path. The plasma currents in each of the paths oscillate (e.g., reverse direction) at the frequencies of the second power source 119. The electric field generated by the coils 130 and 140 excites the gases into a plasma state, such as a high density plasma. The excited process gases react with the semiconductor substrate 121 to form desired coatings and films (i.e., silicon oxide). Upon completion of the CVD process, the excess process and by-product gases are evacuated from the processing chamber 100 via exhaust port 160 connected to an external evacuation pump (not shown).

FIG. 3 illustrates one embodiment of a switch box 135. The switch 133 is generally a double-throw switch. Those skilled in the art will appreciate, that such connections may be performed using, for example, two single-throw switches and the like. The switch box is adapted to provide power from a power source, such as the second power source 119, which second power source 119 may be a 2 MHz HDP source generator with a frequency band or range as described herein, to the coils 130 and/or 140 when a switch 133 in the switch box is in a first position 133a, and to provide power to a remote plasma source 110 when the switch is in a second position 133b.

If coils 130 and 140 have independent power sources, then a switch box 135 as described herein may be used for each of the second power source 119 and the third power source 129. Additionally, the processing chamber 100 design requirements may only require one of the second power source 119 or the third power source 129 to be coupled to a switch box 135 with the other power source not coupled to a switch box. Alternatively, if a single power source is used to provide power to both coils 130 and 140, then a single switch box 135 may be coupled to both coils 130 and 140.

When the switch 133 is set to the first position 133a, the processing chamber 100 is configured for performing a first plasma process, such as a high density plasma deposition process. During such a process, the process gas is supplied into the chamber and the second power source 119 energizes the process gas to a high density plasma in the process region 170. In the embodiment using independent power sources for coils 130 and 140, the third power source 129 coupled to coils 140 is also provided to form the high density plasma.

When the switch 133 is set to the second position 133b, the processing chamber 100 is configured for performing a second plasma process, such as a cleaning process. During the cleaning process, cleaning gas is delivered into the chamber via the remote plasma source 110, and the second power source 119 applies RF power to the remote plasma source and the cleaning gas is energized to a plasma in the process region 170. The substrate 121 is preferably removed prior to initiating the cleaning process.

The switch 133 may also have one or more additional positions (not shown) for coupling to additional power applications. For example, the processing chamber 100 may have an additional RF power application that can be provided power separate from the coils 130, 140, and the remote plasma source 110. The additional positions may provide for alternative power delivery matters, for example, one position may provide power to the coils 130, another position may provide power to coils 140, and a third position may provide power to both coils 130 and coils 140, in addition to the position providing power to the remote plasma source 110.

In one embodiment of the apparatus, when power is provided to either the coils 130, 140 or the remote plasma source 110, no power is provided to the other component. In one power application using the switch box, when power is provided to the coils 130 and/or coils 140 by the second power source 119, no power is provided to the remote plasma source 110. For example, in the second position 133b, the electrical coupling is as shown in FIG. 5. Conversely, when power is applied to the remote plasma source 110, no power is provided to the coils 130 and/or 140.

In an embodiment using independent power source for the coils 130 and coils 140, a single switch box may be used to apply power from the second power source 119 to the coils 130 and a third power source 129 not coupled to the switch box 135 may provide independent power to the coils 140 when no power is applied to the remote plasma source, and then when the switch is positioned so that power is applied to the remote plasma source and no power is applied to the coils 130, the power provided to the coils by the independent third power source may be ended.

For better performance, connections to contacts for positions 133a, 133b, are provided using conductors (e.g., wires, coaxial cables, and the like) of minimal impedance and length. The switch 133 may be operated manually or, alternatively, by an actuator (e.g., a solenoid, linear motor, and the like), controlled, e.g., by a process chamber controller. Suitable switch boxes include the Vacuum Switch boxes from Jennings Technologies, Inc., of San Jose, Calif.

Suitable match boxes include Ceramic Capacitors of American Technical Ceramics, of Huntington Station, N.Y. and Vacuum Variable Capacitors from Jennings Technologies, Inc., of San Jose, Calif. The match boxes are provided to regulate the RF match (also referred to as a matching network or tuner) that transforms the complex impedance of the process chamber to the resistance required by the RF generator. The match boxes are typically integrated match boxes with, or coupled to, the high density power source and the remote plasma source. The match boxes may be design to regulate one or more power sources of the processing chamber 100, for example, one common match box, or multi match box system, may be coupled to both the second power source 119 and third power source 129.

The second power source, or generator, 119 may be an AC power source coupled to the chamber components. The AC power source may provide a power source from 1 kilowatts (kW) to 10 kilowatts (kW), such as up to 20 kW, for example, the processing system typically draws about 8 kW when processing a 200 mm wafer. It is understood that lower or higher power levels might be appropriate according to the type of process being performed and the size of the substrate.

The AC power source may operate at a variety of frequencies (a frequency band) from about 300 kHz to about 13.56 MHz, such as at frequencies of about 300 kHz, about 400 kHz, about 800 kHz, from about 1.9 MHz to about 2.1 MHz, about 10 MHz, and/or about 13.5 MHz, with appropriate design of the elements of the plasma system. The second power source 119 may have automatic tuning with a frequency sweep of less than +/−10% and a frequency trim of +/−50% for the power match to the respective plasmas. The frequency tuning will compensate for the variation of components and the plasma load and is typically controlled by the match box. One example of the second power source is a 2 MHz HDP source generator with a frequency band.

The second power source 119 could be mounted directly on the chamber structure, thus avoiding long leads to the coils 130, 140 or the remote plasma source 110, and associated electromagnetic radiation, as well as reducing variations in load resulting from long leads. Each coil and generated plasma form a transformer circuit that operates as a toroidal transformer plasma source within the interior of the processing chamber when in operation. The primary circuit of the transformer is the coil, with the plasma serving as the secondary circuit of the transformer.

The chamber body 102 can be made of a conductive material, thus serving as a shield for electronic emissions generated by the transformer plasma sources, since each transformer plasma source is within the processing chamber. This not only reduces unwanted emissions from the system, but also may allow the second power source 119 to operate at frequencies that would otherwise generate an unacceptable level of electronic noise emissions. In such an embodiment, it may be desirable to provide leads from the power source to the chamber that are shielded. The efficient coupling of the transformer plasma source(s) also allow a plasma to be generated over a wide range of pressure, such as from about 500 mTorr to about 10 Torr, and can generate plasma from a wide variety of precursors.

The bias system 150 including the first power source 118, and an optional bias-matching network (not shown), is coupled to the substrate support 112. The bias system capacitively couples the substrate support 112, i.e., the substrate, to conductive (grounded) inner surfaces of the chamber through a common ground (not shown). The bias system serves to enhance the transport of plasma species (e.g. reactive ions or other particles) created by the plasma to the surface of the substrate 121 as the plasma species are biased and driven toward the substrate surface, thereby depositing on or sputtering the substrate surface.

The first power source may be an AC power source which may provide a power source of from 1 kilowatts (kW) to 10 kilowatts (kW), such as up to 20 kW, for example, the processing system typically draws from about 6 to about 8 kW when processing a 300 mm wafer. It is understood that lower or higher power levels might be appropriate according to the type of process being performed and the size of the substrate. The first power source could operate at one or more frequencies from about 300 kHz to about 13.56 MHz, such as at frequencies of about 300 kHz, about 400 kHz, about 800 kHz, from about 1.9 MHz to about 2.1 MHz, about 10 MHz, about 13.5 MHz, with appropriate design of the elements of the plasma system. The first power source may provide a bias power to the substrate support 112 at 10 kW with a frequency of 13.56 MHz.

A remote plasma source 110 is disposed on top of the chamber and is fluidly coupled to the processing chamber 100 via port 120b. The second power source 119 is electrically coupled to the remote plasma source 110 through the switch box 135 and integrated match box 139, such as an integrated fixed match box. The remote plasma source 110 may perform as an optional remote plasma cleaning system to periodically clean deposition residues from chamber components. The cleaning system includes a remote RF plasma generator that creates a plasma from a cleaning gas source such as a fluorine containing compound, for example, molecular fluorine, nitrogen trifluoride, other fluorocarbons or equivalents, in a reactor cavity. The reactive species resulting from this plasma are conveyed to the chamber interior through port 120b.

FIG. 4 is a simplified sectioned perspective view of one embodiment of a remote plasma source 110, also referred to as a multi-core transformer coupled plasma generator. The generator has an inlet 442 for admitting plasma precursor(s) and an outlet 444 that provides plasma to a plasma process, such as a deposition chamber cleaning process. These designations are used solely for purposes of illustration and the actual flow may be reversed in some applications. The generator has an outer shell 446 surrounding each toroidal plasma generator stage and inner shells 445, 447, 449 surrounding the toroidal transformer cores 450, 451, 452. The shells can be made of metal if a non-conductive gap or dielectric spacer 454, 455, 456 is included to prevent eddy currents. The dielectric spacer can be located in different locations around the core. Webs 457 support the generator stages inside the outer shell 446 of the plasma generator, while allowing gas and plasma to flow around each core.

A primary coil (not shown) around each core couples electromagnetic energy to the plasma generator. The electrical leads (not shown) typically lead out from the cores to outside the outer shell through the webs. A bottom portion 458 of the inner shell 447 is shaped to promote a symmetrical flow of plasma around the inner shell. When AC current is provided to the plasma generator under plasma-generating conditions, plasma flows back and forth through the centers of each toroidal plasma generating stage (i.e. each core, primary coil, and inner shell). The toroidal configuration of each stage produces a plasma density distribution that is greater in the center of the generator and generally extends beyond the inner shells. In other words, the toroidal plasma generator produces a plasma with directionality, specifically, with a high plasma concentration extending along the center axis of the cores. This directionality can be a desired attribute in some applications, such as a source for ion implantation or ion milling, or a plasma torch application.

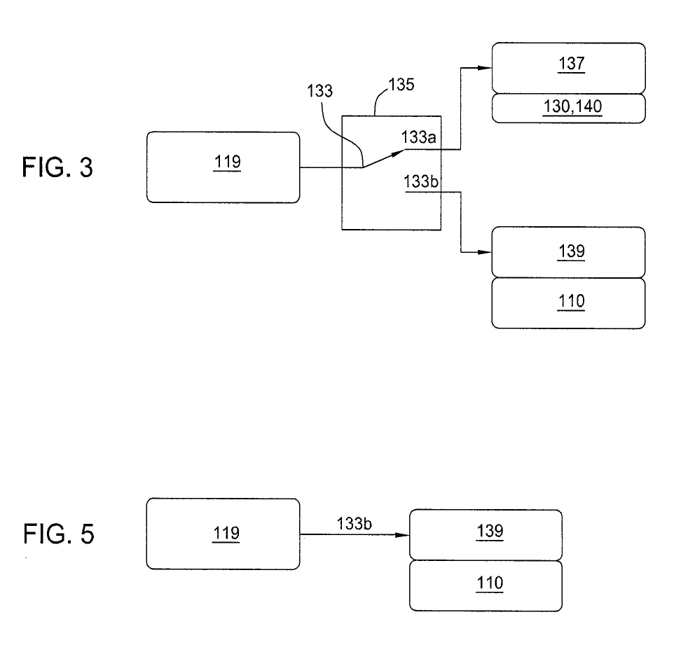

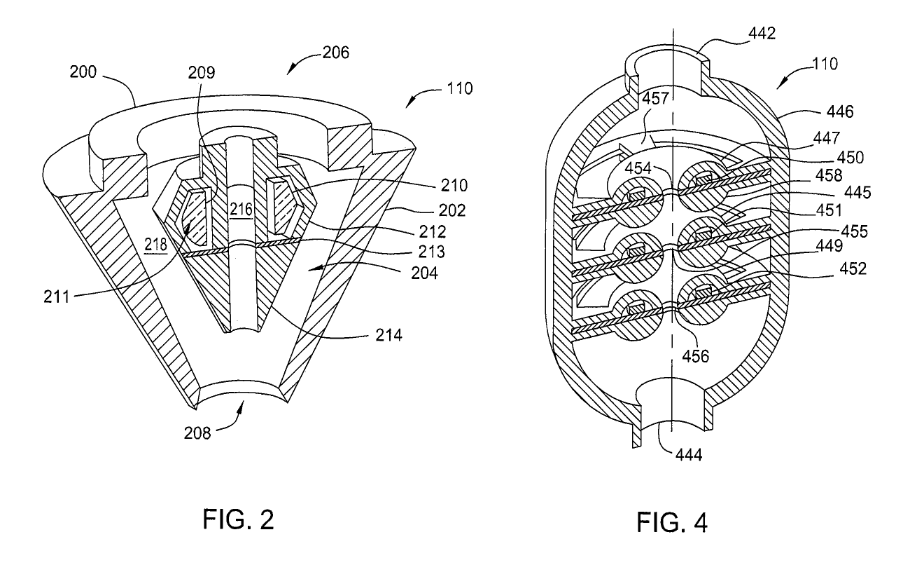

Alternatively, FIG. 2 is a simplified sectioned perspective view of a portion of a plasma generator according to another embodiment of the present invention. The plasma generator in FIG. 2 is also known as a plasma torch head.

The torch head 200 includes an outer nozzle 202 and an inner nozzle 204. Gas from which the plasma is formed enters from the inlet side 206 of the torch head and plasma and gas exit the outlet 208. The inner nozzle 204 includes a toroidal core 210 of a transformer-coupled plasma generator. A primary coil (not shown) couples electro-magnetic energy from an AC power source (not shown). Additional cores and primary coils may be stacked along the center axis of the conduit to promote the directionality of the plasma. In this embodiment, the core has an essentially semicircular cross-section 211 with a long edge 209 parallel to the conduit. The leads (not shown) for the primary coil can be lead through a web, as is described according to reference numeral 457 in FIG. 4, above. The inner nozzle also includes an upper shell 212, a dielectric spacer 213, and a lower shaped portion 214. A conduit 216 extends through the inner nozzle. The upper shell and the lower shaped portion are made of a suitable metal or alloy, such as an aluminum alloy.

Generally speaking, a high-density plasma is formed in the conduit 216 in the portion of the conduit proximate to the core 210, with the plasma current return path through a bypass 218. A plasma initiator device, such as an electric arc or high-frequency parallel plate initiator may be used in some applications to assist in the initial formation of a plasma. Once the plasma is initiated, the toroidal transformer-coupled plasma generator can maintain the plasma over a wide range of operating conditions, such as pressure (e.g., 1 mTorr to 100 Torr) and flow rate

The bypass 218 allows for a separate gas flow that does not flow through the conduit 216. This gas flow can serve many purposes. It can provide cooling to the inner nozzle, mass transport of the plasma out the outlet 208, and can dilute the plasma to reduce recombination. In one embodiment, a separate gas, e.g. propane or hydrogen, is flown through the bypass while another gas, e.g. oxygen, is flown through the conduit. In another embodiment, the same gas is flown through the conduit and the bypass. Some plasma is in the bypass, as well as in the conduit, to complete the secondary circuit around the transformer core. The tapered shape of the outer nozzle provides an increase in velocity and concentration of the plasma and carrier gas exiting the outlet 208. The poloidal flow of plasma around the core 210 provides a high-density plasma extending along the center axis of the nozzle. This directional aspect to the plasma operates in conjunction with the gas flow to efficiently provide plasma at the outlet 208 of the torch head 200, which lies on the centerline with the conduit. Multi-core transformer coupled plasma generator and plasma torch head are more fully described in U.S. Pat. No. 6,755,150, issued on Jun. 29, 2004, which is incorporated by reference herein to the extent not inconsistent with the specification and the recited claims.

Using a toroidal transformer-coupled plasma generator within the torch head has several advantages over conventional arc-type plasma torch heads. First, arc-type plasma generators are typically run at several hundred volts, which can be lethal if an operator comes in contact with the voltage. While the arc electrodes are typically unavailable to the operator during use, exposed powered electrodes or failures in the isolation of high voltages may present a lethal electrical shock hazard. In comparison, the electrical components of the toroidal transformer-coupled plasma generator can be completely enclosed, and remain so even during servicing of the torch head.

Second, the AC power source can be a simple step-up/step down transformer and in some applications might run at the frequency of the line supply (e.g. 60 Hz).

Third, conventional arc-type electrodes are exposed to the plasma and plasma precursor, often causing electrode erosion or contamination. The erosion of the electrodes is exacerbated by the fact that the greatest erosion typically occurs at the point of the electrode, where it is generally desirable to generate the high voltage gradients desired for arc discharge. The toroidal transformer-coupled plasma generator has cover with a relatively high surface area surrounding the core, thus intense field lines intersecting the surface of the cover are substantially avoided. Similarly, the poloidal plasma flux generated by the toroidal core runs essentially parallel to the surface of the cover, thus sputtering or similar damage to the core is substantially eliminated.

Fourth, while arc discharge generators are relatively sensitive to pressure and flows, and may become unstable or extinguish if appropriately stable operating conditions are not established, the transformer-coupled plasma generator can operate over a wide range of pressures and flow rates.

In operation a plasma precursor is flown from an inlet end toward an outlet end of a plasma torch head through a conduit passing through a center of an inner nozzle. The inner nozzle includes a toroidal plasma generator that ionizes the precursor to form a plasma in the center conduit. A carrier gas is flown through an outer passageway formed between the outer surface of the inner nozzle and an inner surface of an outer nozzle to cool the inner nozzle and to assist in the transport of plasma formed in the inner nozzle out the outlet. The order given is merely exemplary, and the steps can be performed in other orders, such as initiating carrier gas flow before or concurrently with the flow of the plasma precursor.

Referring back to FIG. 1A, a deposition and cleaning process may be performed by positioning a substrate into a processing chamber, applying power from the power generator to a high density power source through a switch in the first position, supplying a processing gas into the chamber, generating a plasma of the processing gas in the chamber, performing a plasma enhanced chemical vapor deposition process in the chamber, applying power from the power generator to a remote power source through a switch in the second position, supplying a processing gas into the remote plasma source, generating a plasma of the processing gas in the remote plasma source, and supplying the plasma to the chamber.

Deposition process gases including gaseous compounds supplied from the process gas source (not shown) are introduced through the ports 120a into the process region 170. Deposition gases include material source gases, such as material precursors, for example, silane, dopant precursors, such as ammonia and/or oxygen gas, and optionally, carrier gases, such as argon. The switch, and the resulting power application to the coils 130, 140, is placed in the first position of the switch box for the deposition process.

Cleaning process gases including gaseous compounds supplied from the process gas source (not shown) are introduced through the port 120b into the process region 170. Cleaning gases may include oxygen-containing or fluorine containing gases, such as O₂, C₂F₅H, F₂, NF₃, CF₄, C₃F₈, or SF₆, and combinations thereof, and optionally, carrier gases, such as argon. The switch, and the power application to the remote plasma source 110, is placed in the second position of the switch box for the cleaning process.

While the foregoing is directed to embodiments of the present invention, other and further embodiments of the invention may be devised without departing from the basic scope thereof, and the scope thereof is determined by the claims that follow.

What is claimed is:

1. An apparatus for processing a substrate, comprising:
a power source;
a switch box coupled to the power source and the switch box having a switch interchangeable between a first position and a second position;
a first match box coupled to the switch box;
a plasma generator coupled to the first match box;
a second match box coupled to the switch box; and
a remote plasma source coupled to the second match box.

2. The apparatus of claim 1, wherein the power source is an AC power source adapted to operate at one or more frequencies from about 300 kHz to about 13.56 MHz.

3. The apparatus of claim 1, wherein the power source applies a power from about 1 kilowatts to about 11 kilowatts to a plasma source.

4. The apparatus of claim 1, wherein the power source applies a power from about 1 kilowatts to about 11 kilowatts to a remote plasma source.

5. An apparatus for processing a substrate, comprising:
a chamber body having a dome portion;
a plasma generator disposed on the chamber body;
a remote plasma source disposed on the chamber body;
a switch box coupled to the plasma generator and the remote plasma source with the switch box having a switch interchangeable between a first position and a second position; and
a first power source coupled to the switch box.

6. The apparatus of claim 5, wherein the plasma generator comprises a first plurality of coils disposed on a top portion of the dome portion and a second plurality of coils disposed on a side portion of the dome portion.

7. The apparatus of claim 6, wherein the first power source is electrically coupled to the first plurality of coils when the switch is in the first position.

8. The apparatus of claim 6, further comprising a second power source coupled to the second plurality of coils.

9. The apparatus of claim 6, further comprising a substrate support disposed in the chamber body and a third power source coupled to the substrate support.

10. The apparatus of claim 5, wherein the first power source is an AC power source adapted to operate at one or more frequencies from about 300 kHz to about 13.56 MHz.

11. The apparatus of claim 8, wherein the second power source is an AC power source adapted to operate at one or more frequencies from about 300 kHz to about 13.56 MHz.

12. The apparatus of claim 6, wherein the first power source is electrically coupled to the remote plasma source of coils when the switch is in the second position.

13. The apparatus of claim 5, further comprising a first match box disposed between the switch box and a portion of the plasma generator and a second match box disposed between the switch box and the remote plasma source

14. A method for processing a substrate and processing a chamber, comprising:
positioning a substrate into a processing chamber and the processing chamber comprising:
a chamber body;
a plasma source disposed on the chamber body;
a remote plasma source disposed on the chamber body;
a switch box having first and second switch positions coupled to the plasma source and the remote plasma source; and
a first power source coupled to the switch box;
applying power from the first power source to a portion of the plasma generator through a switch in the first switch position;
supplying a first processing gas into the chamber;
generating a first plasma of the first processing gas in the chamber;
applying power from the first power source to a remote power source through a switch in the second switch position;
supplying a second processing gas into the remote plasma source;
generating a second plasma of the second processing gas in the remote plasma source; and
supplying the second processing gas to the chamber body.

15. The method of claim 14, wherein the first power source is an AC power source adapted to operate at one or more frequencies from about 300 kHz to about 13.56 MHz.

16. The method of claim 15, wherein the first power source supplies a power from about 1 kilowatts to about 11 kilowatts to a plasma generator or the power source supplies a power from about 1 kilowatts to about 11 kilowatts to a remote plasma source.

17. The method of claim 14, wherein the first processing gas is a deposition gas comprises silane and a gas selected from the group of ammonia, oxygen, or combinations thereof.

18. The method of claim 14, wherein the second processing gas is a cleaning gas selected from the group consisting of O₂, C₂F₅H, F₂, NF₃, CF₄, C₃F₈, or SF₆, and combinations thereof.

19. The method of claim 14, wherein the plasma generator comprises a first plurality of coils disposed on a top portion of the dome portion and a second plurality of coils disposed on a side portion of the dome portion.

20. The method of claim 19, further comprising a second power source coupled to the second plurality of coils.
